(19) United States
(12) Patent Application Publication
(10) Pub. No.: US 2025/0323049 A1
(43) Pub. Date: Oct. 16, 2025

(54) METHOD OF GRINDING COMPOSITE WAFER AND METHOD OF GRINDING CHIP-ON-WAFER PACKAGE

(71) Applicant: DISCO CORPORATION, Tokyo (JP)

(72) Inventors: Shinji Yoshida, Tokyo (JP); Keisuke Tomoto, Tokyo (JP)

(21) Appl. No.: 19/173,479

(22) Filed: Apr. 8, 2025

(30) Foreign Application Priority Data
Apr. 12, 2024 (JP) 2024-064612

(51) Int. Cl. H01L 21/304; B24B 7/22; H01L 21/67; H01L 21/687

(52) U.S. Cl. CPC H01L 21/304; B24B 7/228; H01L 21/67253; H01L 21/68764

(57) ABSTRACT

A method of grinding a composite wafer includes the steps of: holding a support wafer of the composite wafer by a chuck table; the chuck table in a radial direction of the chuck table, measuring the thickness of an area which is part of the composite wafer and whose thickness is measured at least during finishing grinding, and storing the measured thickness and XY coordinates of a point of measurement of thickness on a horizontal surface, as thickness data; setting a specified area which is an area whose thickness is specified during the finishing grinding, by using the stored thickness data; and measuring the thickness of the specified area by using the XY coordinates of the specified area, and grinding a top surface of the composite wafer by a grinding stone until a measured thickness becomes equal to a finished thickness set in advance.

### CROSS-REFERENCE TO RELATED APPLICATION

This application claims priority from Japanese Patent Application No. 2024-064612 filed with the Japan Patent Office on Apr. 12, 2024, the entire content of which is hereby incorporated by reference.

### BACKGROUND ART

### 1. Technical Field

The present invention relates to a method of grinding a wafer.

### 2. Related Art

A chip-on-wafer (CoW) package includes a support wafer and a chip provided on the support wafer. As disclosed in Japanese Unexamined Patent Publication No. 2014-165339, when a CoW package is ground, the height of the top surface of the CoW package and the height of a holding surface which holds the CoW package are measured, and a difference between the height of the top surface of the CoW package and the height of the holding surface is calculated as the thickness of the CoW package. The CoW package is ground until this thickness becomes equal to a finished thickness which is set in advance.

### SUMMARY

Known grinding methods are disadvantageous in that the thickness of the chip is different between CoW packages due to a difference in thickness of the support wafer between the CoW packages.

An object of the present invention is therefore to uniformize the thickness of a specific member among members provided on the top surface of a support wafer, between plural CoW packages.

A method (first grinding method) of grinding a composite wafer according to an aspect of the present invention includes the steps of: holding a support wafer of the composite wafer by a chuck table; rotating the chuck table while relatively moving a contactless thickness measurement device and the chuck table in a radial direction of the chuck table, measuring the thickness of an area which is part of the composite wafer and whose thickness is measured by the contactless thickness measurement device at least during finishing grinding, and storing the measured thickness and XY coordinates of a point of measurement of thickness on a horizontal surface, as thickness data; setting a specified area which is an area whose thickness is specified during the finishing grinding, by using the stored thickness data; and measuring the thickness of the specified area by the contactless thickness measurement device by using the XY coordinates of the specified area, and grinding a top surface of the composite wafer by a grinding stone until a measured thickness becomes equal to a finished thickness set in advance.

In the first grinding method, the composite wafer may include the support wafer and chips provided on a top surface of the support wafer, and the area whose thickness is measured may include part of at least one of the chips.

In the first grinding method, the composite wafer may include the support wafer and a device wafer provided on a top surface of the support wafer, and the area whose thickness is measured may include part of the device wafer.

In the first grinding method, the step of setting the specified area may include the sub-steps of: arranging the stored thickness data in XY coordinates in a two-dimensional manner; allowing an operator to set a characteristic area that is an area having a characteristic, in the thickness data arranged in the two-dimensional manner; and sampling the characteristic area from the thickness data by performing pattern matching for the thickness data arranged in the two-dimensional manner, by using the characteristic area, and recognizing the specified area in the thickness data based on a sampling result.

In the first grinding method, the step of setting the specified area may include the sub-step of obtaining an area having a thickness falling within a thickness monitoring range set in advance, by using the stored thickness data, and recognizing the obtained area as the specified area.

A method (second grinding method) of grinding a chip on wafer package in which chips are provided on a top surface of a support wafer and the chips are sealed with a sealant, according to another aspect of the present invention, includes the steps of: holding a support wafer of the chip on wafer package by a chuck table; rotating the chuck table while relatively moving a contactless thickness measurement device and the chuck table in a radial direction of the chuck table, measuring (i) the thickness of the sealant from a top surface of the support wafer to a top surface of the sealant, which is the thickness of the sealant provided on the top surface of the support wafer of the chip on wafer package, and (ii) the thickness of the sealant from a top surface of at least one of the chips to the top surface of the sealant, which is the thickness of the sealant provided on the top surface of the at least one of the chips, at least at a part whose thickness is measured by the contactless thickness measurement device during finishing grinding, and storing the measured thickness and XY coordinates of a point of measurement of thickness on a horizontal surface, as thickness data; setting a specified area which is an area whose thickness is specified during the finishing grinding, by using the stored thickness data; and measuring the thickness of the specified area by the contactless thickness measurement device by using the XY coordinates of the specified area, and grinding a top surface of the chip on wafer package by a grinding stone until a measured thickness becomes equal to a finished thickness set in advance.

In the second grinding method, the step of setting the specified area may include the sub-steps of: arranging the stored thickness data in XY coordinates in a two-dimensional manner; allowing an operator to set a characteristic area that is an area having a characteristic, in the thickness data arranged in the two-dimensional manner; and sampling the characteristic area from the thickness data by performing pattern matching for the thickness data arranged in the two-dimensional manner, by using the characteristic area, and recognizing the specified area in the thickness data based on a sampling result.

In the second grinding method, the step of setting the specified area may include the sub-step of obtaining an area having a thickness falling within a thickness monitoring range set in advance, by using the stored thickness data, and recognizing the obtained area as the specified area.

In the first grinding method and the second grinding method, thickness of the chips, the device wafer, or the sealant, which are members on the support wafer, is measured by the contactless thickness measurement device. On this account, even when the thickness of the support wafer is different between chip-on wafer packages, it is possible to uniformize the thickness of the chips, the device wafer, or the sealant between the chip-on-wafer packages.

In addition to the above, the top surface of the chip-on-wafer package (the top surface of at least one of the chips, the device wafer, or the sealant) is ground until the thickness of the specified area, which is to be specified to the finished thickness in the finishing grinding step, becomes equal to the predetermined finished thickness. It is therefore possible to further suitably control the thickness of the specified area.

### BRIEF DESCRIPTION OF THE DRAWINGS

FIG. 1 is an oblique perspective view showing an arrangement of a grinding apparatus.

FIG. 2 illustrates an arrangement of a chip on-wafer package.

FIG. 3 illustrates a thickness data storage step.

FIG. 4 is a top view showing measurement lines which are tracks of a contactless thickness measurement device.

FIG. 5 is a top view showing an example of an image of the top surface of the chip on-wafer package.

FIG. 6 illustrates a finishing grinding step.

FIG. 7 illustrates an arrangement of a composite wafer including a device wafer.

FIG. 8 illustrates an arrangement of another chip on-wafer package.

FIG. 9 illustrates a thickness data storage step.

FIG. 10 is a graph showing thickness data.

FIG. 11 is a graph showing thickness data.

FIG. 12 is an oblique perspective view showing an arrangement of another grinding apparatus.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

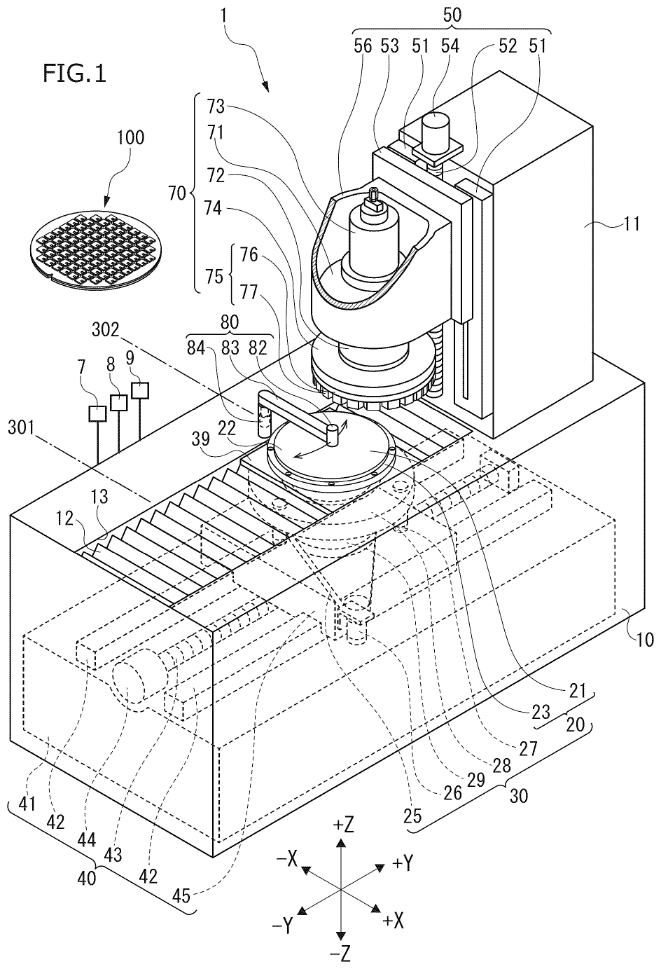

As shown in FIG. 1, a grinding apparatus 1 that is a processing apparatus of the present embodiment is configured to grind a wafer 100 held on a holding surface 22 of a chuck table 20, by using grinding stones 77.

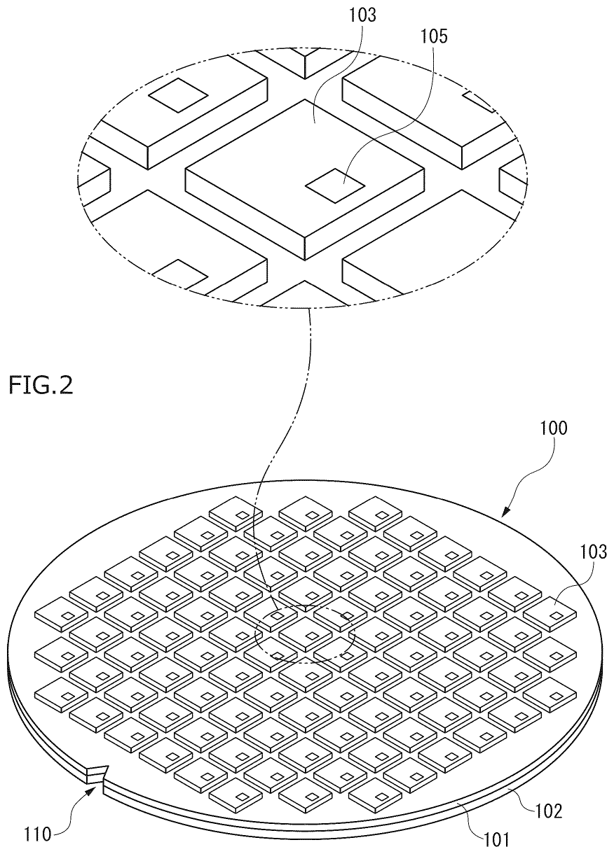

As shown in FIG. 2, the wafer 100 is an example of a composite wafer, and is a circular chip-on-wafer (CoW) package. The wafer 100 includes a support wafer 101, a tape 102 joined to the bottom surface of the support wafer 101, and chips 103 formed on the top surface of the support wafer 101. Each chip 103 is a plate substantially rectangular in shape, and is fixed to the support wafer 101 by, for example, molding. A part of the outer edge of the wafer 100 is cut out to form a notch 110.

As shown in FIG. 1, the grinding apparatus 1 includes a base 10 which is rectangular parallelepiped in shape, a column 11 extending upward, a controller 7 configured to control components of the grinding apparatus 1, and a storage 8.

In the base 10, an opening 13 is formed on the top surface side. In the opening 13, a wafer holding mechanism 30 is provided.

The wafer holding mechanism 30 includes the chuck table 20 which has the holding surface 22 for holding the wafer 100, a chuck table base 29 which supports the chuck table 20, a rotating mechanism 26 which is connected to the base end side of the chuck table base 29 through an endless belt 25, a supporter 28 which supports the chuck table base 29, and supporting pillars 27 which support the supporter 28.

The chuck table 20 includes a porous member 21 and a frame 23 which accommodates the porous member 21 so that the top surface of the porous member 21 is exposed. The top surface of the porous member 21 is the holding surface 22 arranged to suck and hold the wafer 100. Due to communication with a suction source (not illustrated), the holding surface 22 sucks and holds the tape 102 side of the wafer 100.

The rotating mechanism 26 includes a motor and a drive pulley, and is configured to rotate the chuck table base 29 by rotating the endless belt 25. As a result, the chuck table 20 supported by the chuck table base 29 rotates about a table rotational axis which passes through the center of the holding surface 22.

In the surrounding of the chuck table 20, a cover plate 39 is provided to move along a Y-axis direction together with the chuck table 20. The cover plate 39 is connected to a bellows cover 12 which expands and contracts in the Y-axis direction. Below the wafer holding mechanism 30, a Y-axis direction movement mechanism 40 is provided.

The Y-axis direction movement mechanism 40 is configured to relatively move the chuck table 20 and grinding stones 77 of a grinding mechanism 70 in the Y-axis direction which is in parallel to the holding surface 22. In the present embodiment, the Y-axis direction movement mechanism 40 is configured to move the wafer holding mechanism 30 including the chuck table 20 in the Y-axis direction relative to the grinding mechanism 70.

The Y-axis direction movement mechanism 40 includes a pair of Y-axis guide rails 42 which is in parallel to the Y-axis direction, a Y-axis movement table 45 which slides on these Y-axis guide rails 42, a Y-axis ball screw 43 which is in parallel to the Y-axis guide rails 42, a Y-axis motor 44 which is connected to the Y-axis ball screw 43, and a holding base 41 which holds the foregoing members.

The Y-axis movement table 45 is provided on the Y-axis guide rails 42 to be slidable. To the Y-axis movement table 45, a nut (not illustrated) is fixed. Into this nut, the Y-axis ball screw 43 is screwed. The Y-axis motor 44 is connected to one end portion of the Y-axis ball screw 43.

In the Y-axis direction movement mechanism 40, as the Y-axis motor 44 rotates the Y-axis ball screw 43, the Y-axis movement table 45 moves in the Y-axis direction along the Y-axis guide rails 42. On the Y-axis movement table 45, the wafer holding mechanism 30 is placed. On this account, in accordance with the movement of the Y-axis movement table 45 in the Y-axis direction, the wafer holding mechanism 30 including the chuck table 20 moves in the Y-axis direction.

In the present embodiment, the chuck table 20 of the wafer holding mechanism 30 is moved by the Y-axis direction movement mechanism 40 along the Y-axis direction, between a holding position 301 which is on a −Y direction side and where the wafer 100 is held on the holding surface 22 and a processing position 302 which is on a +Y direction side and where the wafer 100 is ground by the grinding mechanism 70.

At a rear part (on the +Y direction side) of the top surface of the base 10, the column 11 is erected. On the front surface of the column 11, the grinding mechanism 70 configured to grind the wafer 100 and a vertical movement mechanism 50 are provided.

The vertical movement mechanism 50 is configured to relatively move the chuck table 20 and the grinding stones 77 of the grinding mechanism 70 in a Z-axis direction (grinding feed direction) which is perpendicular to the holding surface 22. In the present embodiment, the vertical movement mechanism 50 is configured to move the grinding mechanism 70 including the grinding stones 77 in the Z-axis direction relative to the chuck table 20.

The vertical movement mechanism 50 includes a pair of Z-axis guide rails 51 which is in parallel to the Z-axis direction, a Z-axis movement table 53 which slides on these Z-axis guide rails 51, a Z-axis ball screw 52 which is in parallel to the Z-axis guide rails 51, a Z-axis motor 54 which is connected to the Z-axis ball screw 52, and a holder 56 which is attached to the Z-axis movement table 53. The holder 56 holds the grinding mechanism 70.

The Z-axis movement table 53 is provided on the Z-axis guide rails 51 to be slidable. To the Z-axis movement table 53, a nut (not illustrated) is fixed. Into this nut, the Z-axis ball screw 52 is screwed. The Z-axis motor 54 is connected to one end portion of the Z-axis ball screw 52.

In the vertical movement mechanism 50, as the Z-axis motor 54 rotates the Z-axis ball screw 52, the Z-axis movement table 53 moves in the Z-axis direction along the Z-axis guide rails 51. As a result, the holder 56 attached to the Z-axis movement table 53 and the grinding mechanism 70 held by the holder 56 move in the Z-axis direction together with the Z-axis movement table 53.

The grinding mechanism 70 is configured to grind the wafer 100 which is sucked and held on the holding surface 22. The grinding mechanism 70 includes a spindle housing 71 which is fixed to the holder 56, a spindle 72 which is rotatably held by the spindle housing 71, a spindle motor 73 which is configured to rotationally drive the spindle 72, a wheel mount 74 which is attached to the lower end of the spindle 72, and a grinding wheel 75 which is mounted on the wheel mount 74.

The spindle housing 71 is held by the holder 56 to extend in the Z-axis direction. The spindle 72 extends in the Z-axis direction to be orthogonal to the holding surface 22 of the chuck table 20, and is rotatably supported by the spindle housing 71.

The spindle motor 73 is connected to the upper end side of the spindle 72. This spindle motor 73 rotates the spindle 72 about an axis extending in the Z-axis direction.

The wheel mount 74 is disc-shaped and fixed to the lower end (leading end) of the spindle 72. The wheel mount 74 supports the grinding wheel 75.

The grinding wheel 75 is substantially identical with the wheel mount 74 in outer diameter. The grinding wheel 75 includes an annular wheel base 76 made of a metal material.

Along the entire circumference of the bottom surface of the wheel base 76, the grinding stones 77 are fixed in an annular manner. The grinding stones 77 are rotated by the spindle motor 73 together with the spindle 72 and grind the top surface of the wafer 100 which is held by the chuck table 20. The chip 103 is formed on this top surface.

The grinding apparatus 1 includes a touch panel 9. The touch panel 9 is configured to display various sets of information regarding the grinding apparatus 1. The touch panel 9 is used for setting various sets of information, too. As such, the touch panel 9 functions as both an inputter used for inputting information and a display configured to display information.

Beside the opening 13 of the base 10, a thickness measuring mechanism 80 is provided to measure the thickness of the wafer 100 by contactless.

The thickness measuring mechanism 80 includes a contactless thickness measurement device 82 configured to measure the thickness of the wafer 100 by contactless, an arm portion 83 supporting the contactless thickness measurement device 82 at the leading end, and a supporter 84 capable of supporting and turning the arm portion 83. The supporter 84 allows the contactless thickness measurement device 82 to turn and move along a radial direction of the chuck table 20 (holding surface 22) to pass through the center of the holding surface 22.

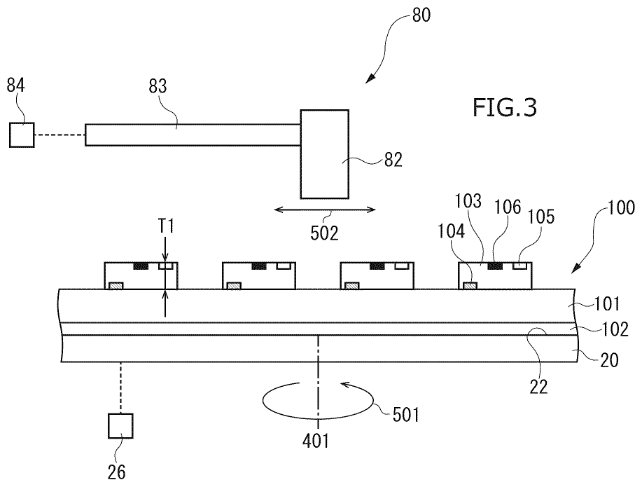

The contactless thickness measurement device 82 is configured to measure the thickness of the wafer 100 held by the chuck table 20. In particular, in the present embodiment, the contactless thickness measurement device 82 is configured to measure the thickness of the chips 103 on the wafer 100. The contactless thickness measurement device 82 measures the thickness T1 (see FIG. 3) of the chip 103 by means of spectral interference in such a way that measurement light having a wavelength that allows the light to pass through the chip 103 of the wafer 100 is applied to the chip 103 from above the wafer 100 and top-surface-reflected light reflected on the top surface of the chip 103 and bottom surface-reflected light passing through the chip 103 and reflected on the bottom surface of the chip 103 are received.

The controller 7 includes members such as a CPU configured to perform computation based on a control program and storage media such as a memory. The controller 7 controls the above-described members of the grinding apparatus 1 so as to centrally control constituent features of the grinding apparatus 1. For example, the controller 7 controls the above-described members of the grinding apparatus 1 so as to grind the wafer 100.

The storage 8 is used for storing information necessary for allowing the controller 7 to perform the control.

The following will describe a method of grinding the wafer 100, which is under the control of the controller 7. The method of grinding the wafer 100 of the present embodiment is equivalent to a method of grinding a wafer 100 that is a chip-on-wafer package in which chips 103 are provided on the top surface of a support wafer 101.

### [Holding Step]

In the method of grinding the wafer 100 of the present embodiment, to begin with, a holding step is performed. In this step, the support wafer 101 of the wafer 100 is held by the chuck table 20. To be more specific, to begin with, the controller 7 controls the Y-axis direction movement mechanism 40 to provide the wafer holding mechanism 30 including the chuck table 20 at the holding position 301 on the −Y direction side, which is for holding the wafer 100 by the chuck table 20.

Subsequently, an operator or an unillustrated transportation device places the support wafer 101 side (tape 102 side) of the wafer 100 on the holding surface 22 of the chuck table 20 so that the top surface of the wafer 100 where the chips 103 are formed faces up. Thereafter, as the controller 7 causes the holding surface 22 to communicate with a suction source, the wafer 100 is sucked and held on the holding surface 22.

### [Thickness Data Storage Step]

After the holding step, a thickness data storage step is performed. In this step, the chuck table 20 is rotated while the contactless thickness measurement device 82 and the chuck table 20 are relatively moved in a radial direction of the chuck table 20, the thickness of a predetermined area of the wafer 100 is measured, and the measured thickness and XY coordinates on a horizontal surface of each point of measurement of thickness are stored as thickness data. This predetermined area is an area where the thickness is measured by the contactless thickness measurement device 82 at least during subsequent finishing grinding, and is an area including at least part of a chip 103. In the present embodiment, the predetermined area is substantially the entire surface of the wafer 100, the thickness measuring points are set over substantially the entire surface of the wafer 100, and the thickness of substantially the entire surface of the wafer 100 (i.e., the thickness of all chips 103) is measured.

To be more specific, to begin with, the controller 7 controls the Y-axis direction movement mechanism 40 to provide the wafer holding mechanism 30 including the chuck table 20 at the processing position 302 on the +Y direction side, where the thickness of the wafer 100 can be measured by the thickness measuring mechanism 80.

Subsequently, as shown in FIG. 3, the controller 7 causes the rotating mechanism 26 to rotate (in a direction indicated by an arrow 501) the chuck table 20 about a rotational axis 401 passing through the center of the holding surface 22. Furthermore, the controller 7 causes the supporter 84 to turn the arm portion 83 and the contactless thickness measurement device 82, so as to move the contactless thickness measurement device 82 in a radial direction of the chuck table 20 (wafer 100) (in a direction indicated by an arrow 502). In this way, the controller 7 provides the contactless thickness measurement device 82 at the thickness measuring points of the wafer 100 held by the chuck table 20 in order, and measures the thickness of the entire surface including all chips 103.

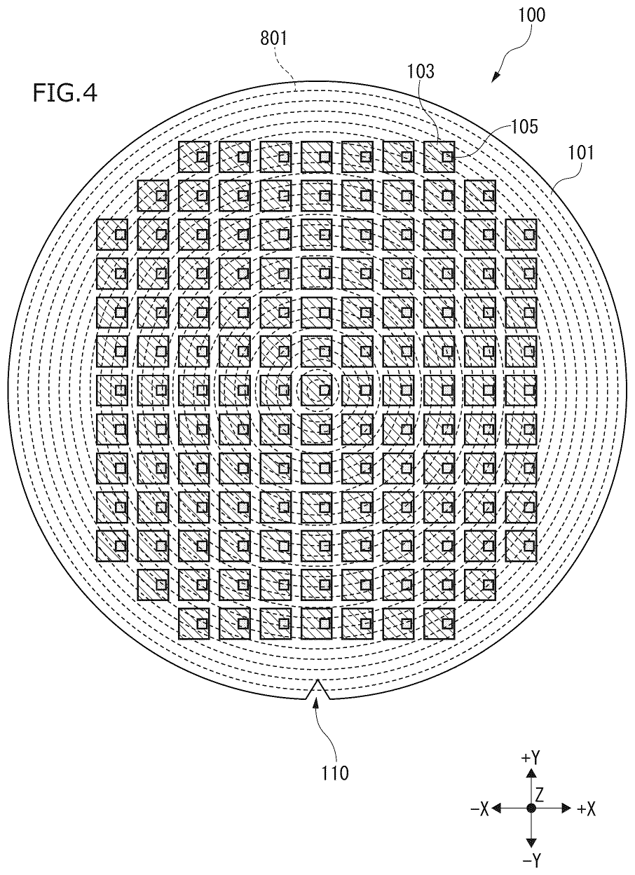

FIG. 4 shows measurement lines 801 that are tracks of the contactless thickness measurement device 82. The thickness measuring points of the wafer 100 are provided along these measurement lines 801. In this way, according to the present embodiment, while rotating the chuck table 20, the controller 7 causes the contactless thickness measurement device 82 to turn outward from the inner side, for example, in a radial direction of the chuck table 20, so that concentric measurement lines 801 are formed on the top surface of the wafer 100. With this arrangement, the thickness of the entire surface of the wafer 100 is measured.

In doing so, with reference to the notch 110 of the wafer 100, the controller 7 obtains two-dimensional coordinates (XY coordinates with reference to the notch 110) of the thickness measuring points of the wafer 100 on a horizontal surface, which are along the measurement lines 801. The controller 7 then stores, in the storage 8, the relationship (combination) between the XY coordinates of each thickness measuring point of the wafer 100 and the thickness at the each thickness measuring point, as thickness data.

### [Area Setting Step]

Subsequent to the thickness data storage step, an area setting step is performed. In this step, a specified area whose thickness is to be specified during the finishing grinding is set by using the thickness data stored in the thickness data storage step. This specified area is an area whose thickness in a chip 103 is to be specified, i.e., an area that is specified to have a finished thickness in the subsequent finishing grinding step.

To be more specific, in the area setting step of the present embodiment, a two-dimensional arrangement step, a characteristic area setting step, and a first specified area recognition step are performed.

### [Two-Dimensional Arrangement Step]

In this step, sets of the thickness data stored in the thickness data storage step are plotted in XY coordinates in a two-dimensional manner. In the present embodiment, an image of the top surface of the wafer 100 (an image of the chips 103) is formed as thickness data in XY coordinates arranged in two dimensions, by converting the thickness data obtained in the thickness data storage step into an image (i.e., an image based on image components such as brightness, color tone, or color difference) (image formation step).

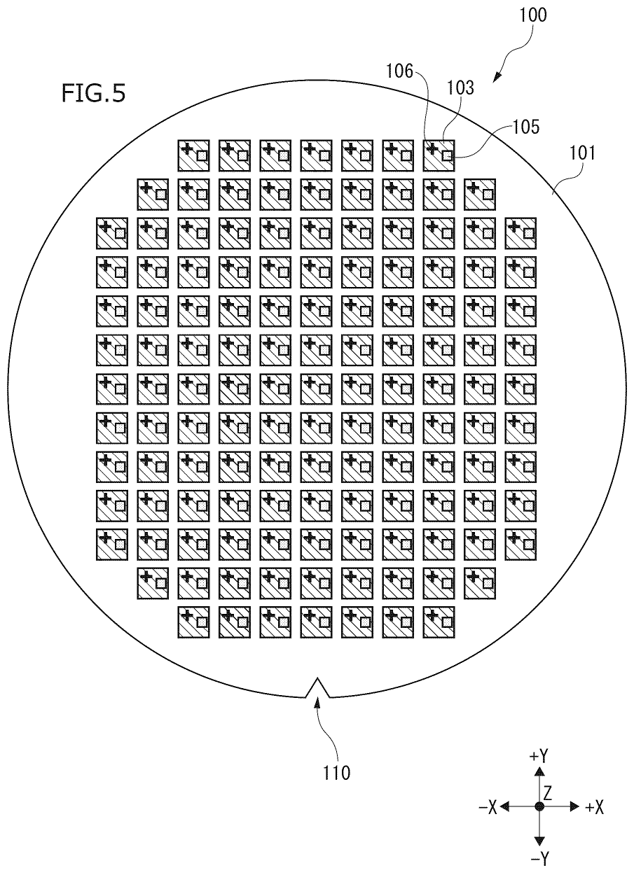

FIG. 5 shows an example of such an image of the top surface of the wafer 100 formed in this step. In the example shown in this figure, each chip 103 is displayed with an image component (e.g., color tone) corresponding to its thickness.

On each chip 103, a device is formed. Depending on the device, there may be an area where the thickness of the chip 103 is measured to be thinner than the actual thickness. For example, in the example shown in FIG. 3, a device including a film 104 is formed on each chip 103, and the thickness of an area where the film 104 of the device is formed is measured to be thinner than the actual thickness in the chip 103.

Due to this, in the present embodiment, as shown in FIG. 3, the operator sets an area which is not an area including the film 104 of the device on the chip 103 (in other words, which is not an area whose thickness is measured to be thinner than the actual thickness), as an area whose thickness in the chip 103 is to be specified, i.e., a specified area 105 whose thickness is to be specified to a finished thickness in the subsequent finishing grinding step.

In the area whose thickness is measured to be thinner than the actual thickness, for example, a nitride film is formed as the film 104. The contactless thickness measurement device 82 may erroneously measure the thickness of the chip 103 to be thinner than the actual, because the device receives reflected light refracted by the nitride film. In other words, the thickness measured by the contactless thickness measurement device 82 may be a value different from the actual thickness.

Apart from the nitride film, an oxide film or a wiring layer made of copper or aluminum may be used as the film 104. A measurement result of the contactless thickness measurement device 82 is influenced by, for example, an adhesive material. Examples of the adhesive material (material used for joining) include an underfill material such as epoxy resin and acrylic resin. Another factor influencing on a measurement result of the contactless thickness measurement device 82 is a bump provided on the joining surface.

In this way, members influencing on a measurement result of the contactless thickness measurement device 82 are often formed on the entire surface of the wafer 100. On this account, such a member influencing on a measurement result may be included in the specified area 105. Due to this, the grinding apparatus 1 may include a correction setter which is configured to, when the specified area 105 is set, set (perform) correction of a measurement value for correcting the measured thickness of the specified area 105 to the actual thickness.

### [Characteristic Area Setting Step]

After the two-dimensional arrangement step, a characteristic area setting step is performed. In this step, in the thickness data arranged in a two-dimensional manner, the operator sets a characteristic area (key pattern area) that is an area having a characteristic. In the present embodiment, the operator sets the characteristic area by using an image (see FIG. 5) of the top surface of the wafer 100, which is the thickness data arranged in a two-dimensional manner.

To be more specific, the controller 7 displays the image of the top surface of the wafer 100 shown in FIG. 5 on the touch panel 9. The operator then sets a characteristic area in the image displayed on the touch panel 9, by using an input device such as a mouse. The characteristic area is, for example, an area having a characteristic pattern (e.g., a shape or a group of thickness values) as compared to other areas, and is suitable for pattern matching. In the present embodiment, the operator sets a cross-shaped part on the chip 103 as a characteristic area 106.

In accordance with the setting of the characteristic area 106 by the operator, the controller 7 obtains the pattern of the characteristic area 106 set by the operator. It is noted that the characteristic area may be identical with the specified area whose thickness is to be specified in the chip 103.

In this step, furthermore, the operator sets the specified area 105 (i.e., the position of the specified area 105). That is to say, the operator sets the positional relationship between a characteristic area 106 and a specified area 105 whose thickness is to be specified in the chip (device) 103, by using the touch panel 9, for example. To put it differently, the relationship between the coordinates of the center of the characteristic area 106 and the coordinates of the center of the specified area 105 whose thickness is to be specified is set. Accordingly, as the positional relationship between the characteristic area 106 and the specified area 105, the controller 7 stores the distance in the X direction and the distance in the Y direction between the center of the characteristic area 106 and the center of the specified area 105 whose thickness is to be specified, in the storage 8.

### [First Specified Area Recognition Step]

After the characteristic area setting step, a first specified area recognition step is performed. In this step, by perform pattern matching for the thickness data arranged in a two-dimensional manner by using the characteristic area 106, a characteristic area 106 is sampled from the thickness data, and based on the sampling result, the position of the specified area 105 (area whose thickness is measured by the contactless thickness measurement device 82 during the finishing grinding) in the thickness data is recognized by using the distance in the X direction and the distance in the Y direction between the characteristic area 106 and the specified area 105, which are stored in advance.

In the present embodiment, the controller 7 performs pattern matching for an image of the top surface of the wafer 100, which is the thickness data arranged in a two-dimensional manner, by using the pattern (shape or group of thickness values) of the characteristic area 106 set by the operator. In this case, the controller 7 obtains the XY coordinates of plural characteristic areas 106 (characteristic area 106 of each chip 103) in the image of the top surface of the wafer 100 by sampling the pattern of the characteristic area 106 from the image of the top surface. The controller 7 then recognizes the XY coordinates of plural specified areas 105 (specified area 105 of each chip 103) whose thickness is measured by the contactless thickness measurement device 82 during the finishing grinding from the sampled characteristic area 106, based on, for example, the positional relationship between the characteristic area 106 and the specified area 105 obtained in advance (i.e., the distance in the X direction and the distance in the Y direction between the characteristic area 106 and the specified area 105).

### [Finishing Grinding Step]

After the area setting step (first specified area recognition step), the finishing grinding step is performed. In this step, by using the XY coordinates of the specified areas 105 set in the area setting step, the thickness of each specified area 105 is measured by the contactless thickness measurement device 82, and the top surface of the wafer 100 is ground by the grinding stones 77 until each measured thickness becomes equal to the finished thickness set in advance.

To be more specific, the controller 7 descends the grinding mechanism 70 by using the vertical movement mechanism 50 while rotating the grinding stones 77 of the grinding mechanism 70 and the chuck table 20, with the result that the top surface of the wafer 100 (i.e., the top surfaces of the chips 103) held by the chuck table 20 is ground by the grinding stones 77. In doing so, the controller 7 measures the thickness of the specified area 105 of the ground chip 103 by using the thickness measuring mechanism 80, and grinds the chip until the thickness of the specified area 105 reaches the predetermined finished thickness.

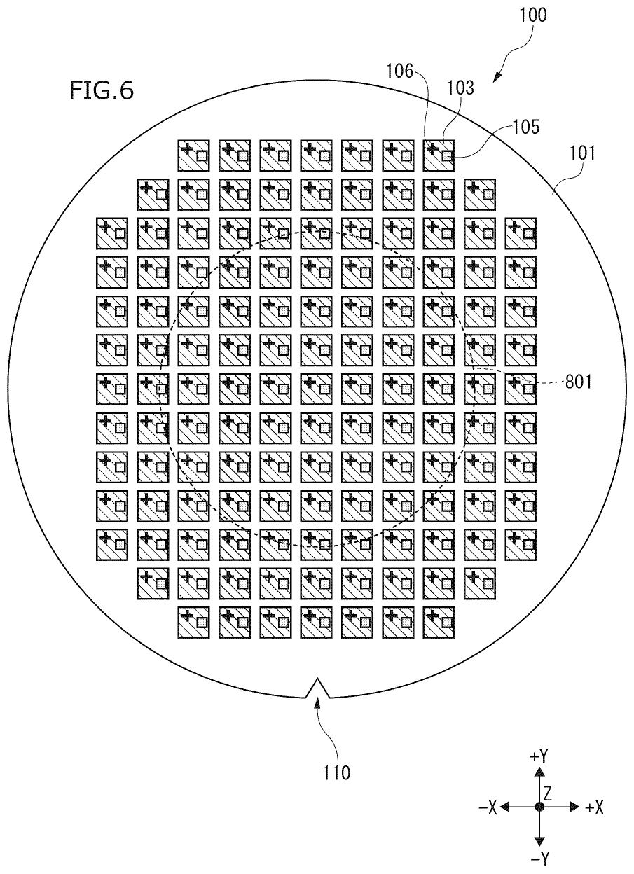

To put it differently, in the finishing grinding, as shown in FIG. 6, the controller 7 measures the thickness at thickness measuring points provided along the measurement lines 801 on the top surface of the wafer 100 (FIG. 6 shows only one of the measurement lines 801) by turning the arm portion 83 and the contactless thickness measurement device 82 (see FIG. 3) by the supporter 84, so as to obtain the relationship between the XY coordinates of each thickness measuring point and the thickness at the each thickness measuring point. The controller 7 then samples only the thickness of the specified area 105 from the thickness of each of the thickness measuring points measured along the measurement line 801, by using the XY coordinates of the specified area 105 obtained in a measurement target recognition step, and the grinding is performed until the sampled thickness becomes equal to the predetermined finished thickness.

As described above, in the present embodiment, the contactless thickness measurement device 82 measures the thickness of the specified area 105 of the chip 103. On this account, even when the thickness of the support wafer 101 is different between the wafers 100, it is possible to uniformize the thickness of the specified area 105 of the chip 103 between the wafers 100.

In the present embodiment, in the finishing grinding step, the chip 103 is ground until the thickness of the specified area 105, which is to be specified to the finished thickness, becomes equal to the predetermined finished thickness. It is therefore possible to suitably control the thickness of the specified area 105 in the chip 103.

In the present embodiment, in the area setting step, an area excluding an area including the film 104 in the chip 103 is set as the specified area 105. As described above, it is difficult for the contactless thickness measurement device 82 to accurately measure the thickness of the area including the film 104 in the chip 103. On this account, in the present embodiment, an area where the thickness of the chip 103 can be accurately measured by the contactless thickness measurement device 82 (i.e., an area excluding the film 104) is set as the specified area 105, and the finishing grinding is performed so that the thickness of the specified area 105 becomes equal to the finished thickness, while monitoring the thickness of the specified area 105. It is therefore possible to further suitably control the thickness of the specified area 105.

While in the present embodiment the chip 103 attached onto the support wafer 101 is ground to have the predetermined finished thickness, a member on the support wafer 101 to be ground to have a predetermined finished thickness may be different from the chip 103. For example, the grinding method of the present embodiment may be used for grinding a device wafer of a wafer (wafer-on-wafer package or laminated wafer) in which the device wafer is attached onto the support wafer 101 to have a predetermined finished thickness.

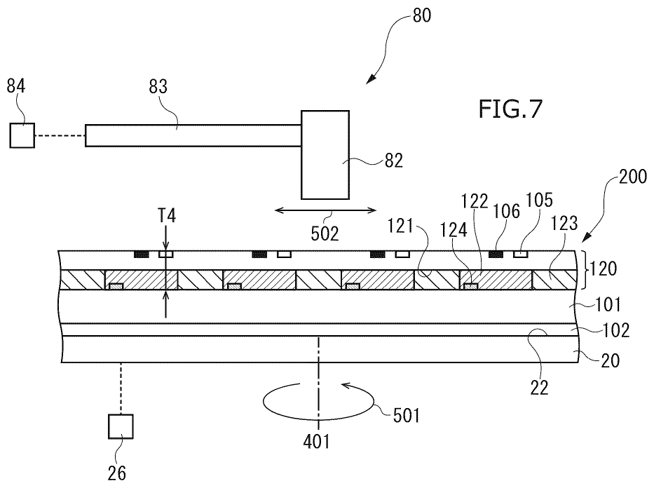

To be more specific, a composite wafer which is ground in the present embodiment is not limited to a chip on wafer package such as the wafer 100, and may be a wafer 200 which is a wafer-on-wafer package having a structure shown in FIG. 7. The wafer 200 includes a device wafer 120 which is laminated on the top surface of the support wafer 101, in place of the chips 103 in the structure of the wafer 100 shown in FIG. 2 and FIG. 3.

This device wafer 120 is laminated onto the support wafer 101 so that a device formation surface 121 of the device wafer 120 opposes the top surface of the support wafer 101. On the device formation surface 121 of the device wafer 120, devices 122 are formed. Between neighboring devices 122, a street 123 is formed. The street 123 includes, for example, a metal wire, an interlayer insulating film, and/or a TEG. On the device 122, a film 124 formed of a nitride film, etc. is formed.

When the wafer 200 is ground, the contactless thickness measurement device 82 shown in FIG. 1 is arranged to be able to measure the thickness of the device wafer 120 of the wafer 200. That is to say, the contactless thickness measurement device 82 measures the thickness T4 (see FIG. 7) of the device wafer 120 by means of spectral interference in such a way that measurement light having a wavelength that allows the light to pass through the device wafer 120 including the devices 122 is applied to the device wafer 120 from above the wafer 200 and top-surface-reflected light reflected on the top surface of the device wafer 120 and bottom-surface-reflected light passing through the device wafer 120 and reflected on the bottom surface of the device wafer 120 are received.

In this wafer 200, due to the presence of the film 124 in the device 122 of the device wafer 120, it is difficult for the contactless thickness measurement device 82 to accurately measure the thickness of the device wafer 120. On this account, when the wafer 200 is ground, an area where the thickness of the device wafer 120 can be accurately measured in the device 122 by using the contactless thickness measurement device 82 is set as a specified area 105, and this specified area 105 is ground to have a thickness equal to a finished thickness, while the thickness of the specified area 105 is monitored.

The following will describe a grinding method for grinding the wafer 200 including the device wafer 120 shown in FIG. 7. This grinding method is a method of grinding a wafer-on-wafer package in which the device wafer 120 on which devices 122 are formed is provided on the top surface of the support wafer 101.

[Holding Step] To begin with, the above-described holding step is performed to hold the wafer 200 by the chuck table 20.

### [Thickness Data Storage Step]

After the holding step, the above-described thickness data storage step is performed. In this step, the chuck table 20 is rotated while the contactless thickness measurement device 82 and the chuck table 20 are relatively moved in a radial direction of the chuck table 20, the thickness of a predetermined area of the device wafer 120 is measured, and the measured thickness and XY coordinates on a horizontal surface of each point of measurement of thickness are stored as thickness data. The predetermined area of the device wafer 120 is an area where the thickness is measured by the contactless thickness measurement device 82 at least during subsequent finishing grinding, and is an area including part of the device wafer 120. The predetermined area may be substantially the entire surface of the device wafer 120. In this case, thickness measuring points are set over substantially the entire surface of the device wafer 120, and the thickness of the entire surface of the device wafer 120 is measured.

To be more specific, as shown in FIG. 7, the controller 7 causes the rotating mechanism 26 to rotate (in a direction indicated by an arrow 501) the chuck table 20 about a rotational axis 401 passing through the center of the holding surface 22 Furthermore, the controller 7 causes the supporter 84 to turn the arm portion 83 and the contactless thickness measurement device 82, so as to move the contactless thickness measurement device 82 in a radial direction of the chuck table 20 (wafer 200) (in a direction indicated by an arrow 502). In this way, the controller 7 provides the contactless thickness measurement device 82 at the thickness measuring points of the device wafer 120 of the wafer 200 held by the chuck table 20 in order, and measures the thickness of the entire surface of the device wafer 120.

In doing so, with reference to a notch 110 of the wafer 200, the controller 7 obtains two-dimensional coordinates (XY coordinates with reference to the notch 110) of the thickness measuring points on a horizontal surface. The controller 7 then stores, in the storage 8, the relationship (combination) between the XY coordinates of each thickness measuring point and the thickness at the each thickness measuring point, as thickness data.

### [Area Setting Step]

After the thickness data storage step, the above-described area setting step is performed. In this step, a specified area whose thickness is to be specified during the finishing grinding is set by using the thickness data stored in the thickness data storage step.

As shown in FIG. 7, the operator sets an area which is not an area including the film 104 of the device on the device wafer 120 (i.e., an area whose thickness is measured to be thinner than the actual thickness), as a specified area 105 that is an area whose thickness in the device wafer 120 is to be specified.

In the area setting step, for example, as described above, a two-dimensional arrangement step, a characteristic area setting step, and a first specified area recognition step are performed.

### [Two-Dimensional Arrangement Step]

In this step, sets of the thickness data stored in the thickness data storage step are plotted in XY coordinates in a two-dimensional manner. For example, as described above, as the thickness data obtained in the thickness data storage step is converted into an image, an image of the top surface of the wafer 200 (an image of the top surface of the device wafer 120) is formed as thickness data in XY coordinates arranged in two dimensions.

### [Characteristic Area Setting Step]

After the two-dimensional arrangement step, the above-described characteristic area setting step is performed. In this step, in the thickness data arranged in a two-dimensional manner, the operator sets a characteristic area that is an area having a characteristic.

To be more specific, by using a mouse, etc., the operator sets a characteristic area 106 on the image of the top surface of the wafer 200 displayed on the touch panel 9 (see FIG. 1). This characteristic area 106 is, for example, an area having a characteristic pattern on the device wafer 120 as compared to other areas, and is suitable for pattern matching. The controller 7 obtains the pattern of the characteristic area 106 set by the operator.

In this step, furthermore, the operator sets the specified area 105 (i.e., the position of the specified area 105). That is to say, by using, for example, the touch panel 9, the operator sets the positional relationship between the characteristic area 106 and the specified area 105 on the device wafer 120 (i.e., the distance in the X direction and the distance in the Y direction between the center of the characteristic area 106 and the center of the specified area 105). The controller 7 then stores this positional relationship in the storage 8.

### [First Specified Area Recognition Step]

After the characteristic area setting step, the above-described first specified area recognition step is performed. In this step, by perform pattern matching for thickness data arranged in a two-dimensional manner by using the characteristic area 106, the controller 7 samples a characteristic area 106 from the thickness data, and based on the sampling result, the controller 7 recognizes the position of the specified area 105 in the thickness data by using the positional relationship between the characteristic area 106 and the specified area 105 stored in advance.

### [Finishing Grinding Step]

After the area setting step (first specified area recognition step), the above-described finishing grinding step is performed. In this step, by using the XY coordinates of the specified areas 105 set in the area setting step, the thickness of each specified area 105 is measured by the contactless thickness measurement device 82, and the top surface of the wafer 200 (top surface of the device wafer 120) is ground by the grinding stones 77 until a measured thickness becomes equal to the finished thickness set in advance.

To be more specific, the controller 7 descends the grinding mechanism 70 by using the vertical movement mechanism 50 while rotating the grinding stones 77 of the grinding mechanism 70 and the chuck table 20, with the result that the top surface of the device wafer 120 held by the chuck table 20 is ground by the grinding stones 77. In doing so, the controller 7 measures the thickness of the specified area 105 of the device wafer 120 by using the thickness measuring mechanism 80, and grinds the wafer until the thickness of the specified area 105 reaches the predetermined finished thickness.

As described above, in this embodiment, the contactless thickness measurement device 82 measures the thickness of the specified area 105 of the device wafer 120. On this account, even when the thickness of the support wafer 101 is different between the wafers 200, it is possible to uniformize the thickness of the specified area 105 of the device wafer 120 between the wafers 200.

In addition to the above, the device wafer 120 is ground until the thickness of the specified area 105, which is to be specified to the finished thickness in the finishing grinding step, becomes equal to the predetermined finished thickness. It is therefore possible to suitably control the thickness of the specified area 105 in the device wafer 120.

In the area setting step, an area excluding an area including the film 124 on the device wafer 120 is set as the specified area 105. As described above, it is difficult for the contactless thickness measurement device 82 to accurately measure the thickness of the area including the film 124 on the device wafer 120. On this account, in the present embodiment, an area where the thickness of the device wafer 120 can be accurately measured (i.e., an area excluding the film 124) by the contactless thickness measurement device 82 is set as the specified area 105, and the finishing grinding is performed so that the thickness of the specified area 105 becomes equal to the finished thickness, while monitoring the thickness of the specified area 105. It is therefore possible to further suitably control the thickness of the specified area 105.

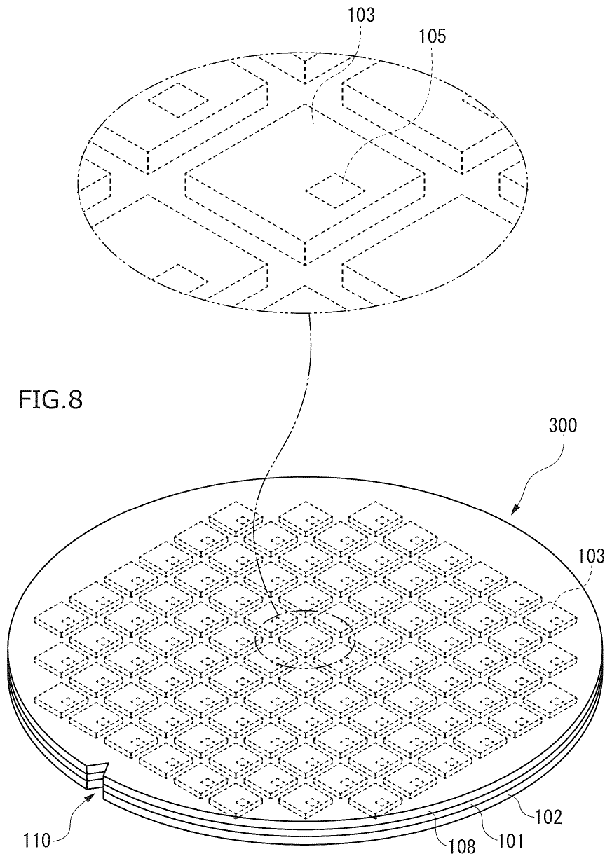

The chip on-wafer package which is ground in the present embodiment may be a wafer 300 shown in FIG. 8. The wafer 300 has the arrangement of the wafer 100 shown in FIG. 2 and further includes a sealant 108 (a layer made of the sealant, molding layer) covering the chips 103 and provided on the top surface of the support wafer 101. The sealant 108 is made of resin or glass, for example.

When the wafer 300 having the sealant 108 is ground, the contactless thickness measurement device 82 shown in FIG. 1 is arranged to be able to measure the thickness of the sealant 108 of the wafer 300. That is to say, the contactless thickness measurement device 82 measures the thickness of the sealant 108 by means of spectral interference in such a way that measurement light having a wavelength that allows the light to pass through the sealant 108 is applied to the sealant 108 from above the wafer 300 and top-surface-reflected light reflected on the top surface of the sealant 108 and bottom surface-reflected light passing through the sealant 108 and reflected on the bottom surface of the sealant 108 are received.

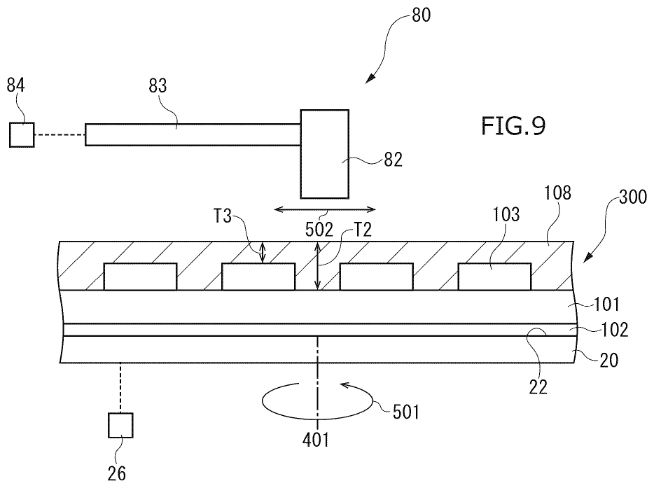

As shown in FIG. 9, the thickness of the sealant 108 includes the thickness T2 of the sealant 108 from the top surface of the support wafer 101 to the top surface of the sealant 108, which indicates the thickness of the sealant 108 provided on the top surface of the support wafer 101, and the thickness T3 of the sealant 108 from the top surface of the chip 103 to the top surface of the sealant 108, which indicates the thickness of the sealant 108 provided on the top surface of the chip 103.

The following will describe a method of grinding the wafer 300, which is under the control of the controller 7. This grinding method is equivalent to a method of grinding a chip-on-wafer package in which chips 103 are provided on the top surface of the support wafer 101 and the chips 103 are sealed with the sealant 108.

### [Holding Step]

In the method of grinding the wafer 300, a holding step is performed in the same manner as in the above-described method of grinding the wafer 100 shown in FIG. 2. That is to say, in this step, the support wafer 101 of the wafer 300 is held by the chuck table 20 shown in FIG. 1. To be more specific, the controller 7 controls the Y-axis direction movement mechanism 40 to provide the wafer holding mechanism 30 including the chuck table 20 at a holding position 301 on the −Y direction side, which is for holding the wafer 300 on the holding surface 22.

Subsequently, an operator or an unillustrated transportation device places the support wafer 101 side (tape 102 side) of the wafer 300 on the holding surface 22 of the chuck table 20 so that the top surface of the wafer 300 where the chips 103 and the sealant 108 are formed faces up. Thereafter, as the controller 7 causes the holding surface 22 to communicate with a suction source, the wafer 300 is sucked and held on the holding surface 22.

### [Top Surface Grinding Step]

Subsequent to the holding step, a top surface grinding step is performed. In this step, the top surface of the sealant 108 of the wafer 300 is ground. To be more specific, to begin with, the controller 7 controls the Y-axis direction movement mechanism 40 to provide the wafer holding mechanism 30 including the chuck table 20 at a processing position 302 on the +Y direction side.

Subsequently, the controller 7 descends the grinding mechanism 70 by using the vertical movement mechanism 50 while rotating the grinding stones 77 of the grinding mechanism 70 and the chuck table 20, with the result that the top surface of the sealant 108 of the wafer 300 held on the holding surface 22 of the chuck table 20 is ground by the grinding stones 77. In doing so, the controller 7 measures, by using the thickness measuring mechanism 80, the thickness of the sealant 108 that is being ground (e.g., the thickness T2 of the sealant 108 from the top surface of the support wafer 101 to the top surface of the sealant 108), and performs the grinding of the top surface until the measured thickness becomes equal to a predetermined value.

When it is found before the top surface grinding step that the top surface of the sealant 108 is flat enough to allow the measurement of the thickness of the sealant 108, the top surface grinding step may be omitted.

### [Thickness Data Storage Step]

After the top surface grinding step, a thickness data storage step is performed. In this step, the chuck table 20 is rotated while the contactless thickness measurement device 82 and the chuck table 20 are relatively moved in a radial direction of the chuck table 20, the thickness of the sealant 108 is measured in a predetermined area of the wafer 300, and the measured thickness and XY coordinates on a horizontal surface of the points of measurement of thickness are stored as thickness data. In the present embodiment, the predetermined area includes a part of the sealant 108 where the thickness is measured by the contactless thickness measurement device 82 at least during subsequent finishing grinding.

In the present embodiment, the predetermined area is substantially the entire surface of the wafer 300, the thickness measuring points are set over substantially the entire surface of the wafer 300, and the thickness of substantially the entire surface of the wafer 300 (i.e. the thickness of the entire surface of the sealant 108) is measured. As described above, the thickness of the sealant 108 includes the thickness (T2 in FIG. 9) of the sealant 108 from the top surface of the support wafer 101 to the top surface of the sealant 108 and the thickness (T3 in FIG. 9) of the sealant 108 from the top surface of the chip 103 to the top surface of the sealant 108.

To be more specific, as shown in FIG. 9, the controller 7 causes the rotating mechanism 26 to rotate (in a direction indicated by an arrow 501) the chuck table 20 about a rotational axis 401 passing through the center of the holding surface 22. Furthermore, the controller 7 causes the supporter 84 to turn the arm portion 83 and the contactless thickness measurement device 82, so as to move the contactless thickness measurement device 82 in a radial direction of the chuck table 20 (wafer 300) (in a direction indicated by an arrow 502). In this way, the controller 7 provides the contactless thickness measurement device 82 at the thickness measuring points of the wafer 300 held by the chuck table 20 in order, and measures the thickness of the entire surface of the sealant 108.

In doing so, with reference to the notch 110 of the wafer 300, the controller 7 obtains two-dimensional coordinates (XY coordinates) of the thickness measuring points of the wafer 300 on a horizontal surface, which are along the measurement lines 801 (see FIG. 4). The controller 7 then stores, in the storage 8, the relationship (combination) between the XY coordinates of each thickness measuring point of the wafer 300 and the thickness of the sealant 108 at the each thickness measuring point, as thickness data.

### [Area Setting Step]

Subsequent to the thickness data storage step, an area setting step is performed. In this step, a specified area whose thickness is to be specified during the finishing grinding is set by using the thickness data stored in the thickness data storage step. This specified area is an area whose thickness in the sealant 108 is to be specified, i.e., an area that is specified to have a finished thickness in the subsequent finishing grinding step.

To be more specific, in the area setting step of the present embodiment, a two-dimensional arrangement step, a characteristic area setting step, and a first specified area recognition step are performed.

### [Two-Dimensional Arrangement Step]

In this step, sets of the thickness data stored in the thickness data storage step are plotted in XY coordinates in a two-dimensional manner. In the present embodiment, an image of the top surface of the wafer 300 (an image of the sealant 108) is formed as thickness data in XY coordinates arranged in two dimensions, by converting the thickness data obtained in the thickness data storage step into an image (i.e., an image based on image components such as brightness, color tone, or color difference) (image formation step). In this image, the sealant 108 is displayed with an image component (e.g., color tone) corresponding to its thickness.

### [Characteristic Area Setting Step]

After the two-dimensional arrangement step, a characteristic area setting step is performed. In this step, in the thickness data arranged in a two-dimensional manner, the operator sets a characteristic area (key pattern area) that is an area having a characteristic. In the present embodiment, the operator sets the characteristic area by using an image of the top surface of the wafer 300 (image of the sealant 108), which is the thickness data arranged in a two-dimensional manner.

To be more specific, the controller 7 displays the image of the top surface of the wafer 300 on the touch panel 9. The operator then sets a characteristic area in the image displayed on the touch panel 9, by using an input device such as a mouse. The characteristic area is, for example, an area suitable for pattern matching.

In accordance with the setting of the characteristic area by the operator, the controller 7 obtains the pattern (shape or a group of thickness value) of the characteristic area set by the operator. It is noted that the characteristic area may be identical with the specified area whose thickness is to be specified in the sealant 108.

In this step, furthermore, the operator sets the specified area (i.e., the position of the specified area). That is to say, the operator sets the positional relationship between a characteristic area and a specified area whose thickness is to be specified in the sealant 108, by using the touch panel 9, for example. To put it differently, the relationship between the coordinates of the center of the characteristic area and the coordinates of the center of the specified area whose thickness is to be specified is set. Accordingly, as the positional relationship between the characteristic area and the specific part, the controller 7 stores the distance in the X direction and the distance in the Y direction between the center of the characteristic area and the center of the specified area whose thickness is to be specified, in the storage 8.

### [First Specified Area Recognition Step]

After the characteristic area setting step, a first specified area recognition step is performed. In this step, by perform pattern matching for thickness data arranged in a two-dimensional manner by using the characteristic area, a characteristic area is sampled from the thickness data, and based on the sampling result, the position of the specified area (area whose thickness is measured by the contactless thickness measurement device 82 during the finishing grinding) in the thickness data is recognized by using the distance in the X direction and the distance in the Y direction between the characteristic area and the specified area, which are stored in advance.

In the present embodiment, the controller 7 performs pattern matching for an image of the top surface of the wafer 300, which is the thickness data arranged in a two-dimensional manner, by using the pattern (shape or group of thickness values) of the characteristic area set by the operator. In this case, the controller 7 obtains the XY coordinates of plural characteristic areas in the image of the top surface of the wafer 300 by sampling the pattern of the characteristic area from the image of the top surface. The controller 7 then recognizes the XY coordinates of the specified area whose thickness is measured by the contactless thickness measurement device 82 during the finishing grinding from the sampled characteristic area, based on, for example, the positional relationship between the characteristic area and the specified area obtained in advance (i.e., the distance in the X direction and the distance in the Y direction between the characteristic area and the specified area).

### [Finishing Grinding Step]

After the area setting step (first specified area recognition step), the finishing grinding step is performed. In this step, by using the XY coordinates of the specified areas set in the area setting step, the thickness of each specified area is measured by the contactless thickness measurement device 82, and the top surface of the wafer 300 is ground by the grinding stones 77 until a measured thickness becomes equal to the finished thickness set in advance.

To be more specific, the controller 7 descends the grinding mechanism 70 by using the vertical movement mechanism 50 while rotating the grinding stones 77 of the grinding mechanism 70 and the chuck table 20, with the result that the top surface of the wafer 300 (i.e., the top surface of the sealant 108) held by the chuck table 20 is ground by the grinding stones 77. In doing so, the controller 7 measures the thickness of the specified area of the sealant 108 by using the thickness measuring mechanism 80, and performs the grinding of the sealant 108 until the thickness of the specified area reaches the predetermined finished thickness.

To put it differently, in the finishing grinding, the controller 7 obtains the relationship between the XY coordinates of each thickness measuring point and the thickness on the top surface of the wafer 300 by turning the arm portion 83 and the contactless thickness measurement device 82 (see FIG. 9) by the supporter 84. The controller 7 then samples only the thickness of the specified area from the thickness measured at each thickness measuring point, by using the XY coordinates of the specified area obtained in the first specified area recognition step, and the grinding is performed until the sampled thickness becomes equal to the predetermined finished thickness.

As described above, in this embodiment, the contactless thickness measurement device 82 measures the thickness of the specified area of the sealant 108. On this account, even when the thickness of the support wafer 101 is different between the wafers 300, it is possible to uniformize the thickness of the specified area of the sealant 108 between the wafers 300.

In addition to the above, the sealant 108 is ground until the thickness of the specified area, which is to be specified to the finished thickness in the finishing grinding step, becomes equal to the predetermined finished thickness. It is therefore possible to suitably control the thickness of the specified area in the sealant 108.

It is noted that the predetermined area in the wafers 100, 200, and 300 where the thickness is measured in the thickness data storage step may not be the entire surface of each of the wafers 100, 200, and 300, and may be set at will on condition that at least a specified area (e.g., a specified area 105 that is part of the chip 103) whose thickness is measured by the contactless thickness measurement device 82 during the finishing grinding is included. Furthermore, it is unnecessary to measure the thickness of all specified areas of the wafers 100, 200, and 300. In the thickness data storage step, measurement of the thickness of only a specified area whose thickness is to be measured by the contactless thickness measurement device 82 in the finishing grinding is required.

In the finishing grinding step, the thickness of all specified areas of each of the wafers 100, 200, and 300 may be measured and the grinding may be performed until the thickness of all specified areas becomes equal to a predetermined finished thickness, or the thickness of at least one specified area specified in advance by the operator may be measured, and the grinding may be performed until the thickness of the at least one specified area becomes equal to a predetermined finished thickness.

According to the embodiment above, as shown in FIG. 4, while rotating the chuck table 20, the controller 7 causes the contactless thickness measurement device 82 to turn in a radial direction of the chuck table 20, so that concentric measurement lines 801 are formed on the top surface of the wafer 100, 200, or 300. In this regard, while rotating the chuck table 20, the controller 7 may cause the contactless thickness measurement device 82 to turn in a radial direction of the chuck table 20, so that one or plural measurement lines 801 is or are formed in a spiral manner on the top surface of the wafer 100, 200, or 300.

In the above-described two-dimensional arrangement step, as the thickness data obtained in the thickness data storage step is converted into an image, an image of the top surface of the wafer 100, 200, or 300 (an image of the chips 103 or the sealant 108) is formed as thickness data arranged in two dimensions. Subsequently, in the characteristic area setting step, the operator sets a characteristic area by using the image. Furthermore, in the first specified area recognition step, the controller 7 samples the characteristic area set by the operator by performing pattern matching for the image.

In regard to the above, in the two-dimensional arrangement step, the thickness data may not be converted to an image, and the thickness values may not be arranged in a two-dimensional manner. In such a case, in the characteristic area setting step, the operator sets, for example, a part which is desired to be set as a characteristic area (e.g., a group of neighboring thickness values, which is to be set as a characteristic area 106 of the chip 103). In the first specified area recognition step, the controller 7 then samples the characteristic area by performing pattern matching for the two-dimensional thickness data by using the thickness of the characteristic area as a pattern.

In the area setting step, furthermore, a specified area whose thickness is to be specified during the finishing grinding is set by using the thickness data stored in the thickness data storage step. In the area setting step of the embodiment described above, the two-dimensional arrangement step, the characteristic area setting step, and the first specified area recognition step are performed. In this regard, in the area setting step, a second specified area recognition step described below may be performed. In this step, the controller 7 obtains an area having a thickness falling within a thickness monitoring range set in advance, by using thickness data stored in the thickness data storage step, and recognizes the obtained area as a specified area.

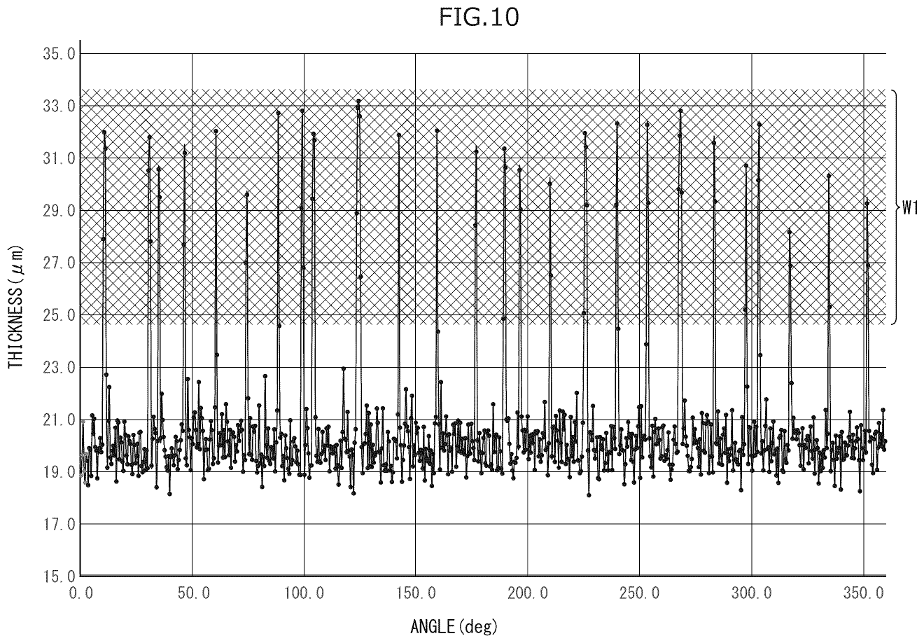

For example, when a part of the chip 103 is to be set as a specified area, assume that thickness data shown in FIG. 10 is obtained in the thickness data storage step. The figure shows each thickness (μm) and an angle (deg) at which the thickness is obtained. This angle indicates an angle corresponding to each thickness measuring point provided along a single circular measurement line 801. For example, the angle is 0 degree at the position of the notch 110. The angle at each thickness measuring point corresponds to XY coordinates on the top surface of the wafer 100. For example, the controller 7 recognizes an area having a thickness falling within a thickness monitoring range W1 (between less than 25 μm to more than 33 μm) in FIG. 10 as a specified area, and obtains the position (XY coordinates) of the recognized specified area.

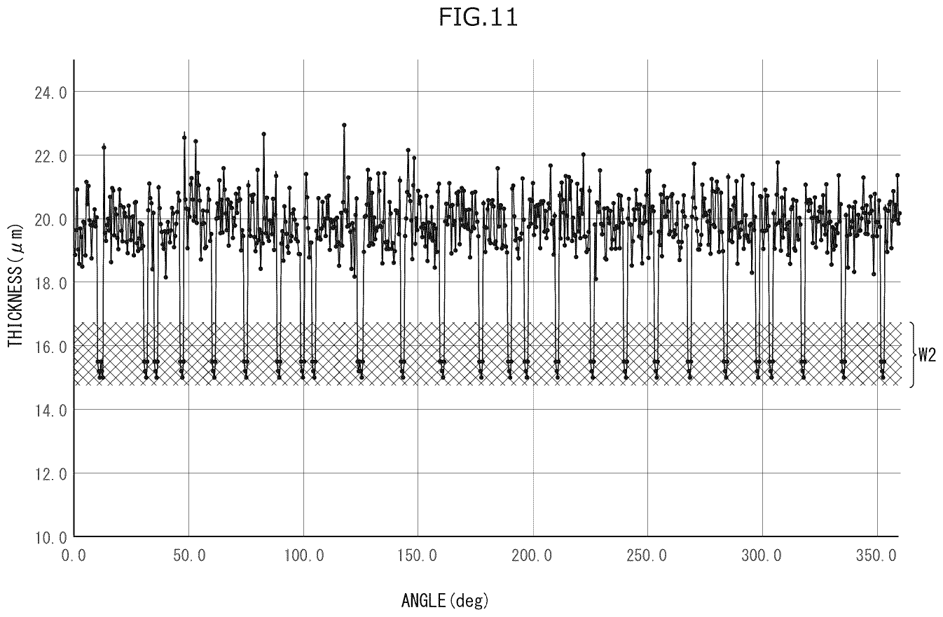

For example, when a part of the sealant 108 is to be set as a specified area, assume that thickness data shown in FIG. 11 is obtained in the thickness data storage step. The figure also shows each thickness (μm) and the above-described angle (deg) at which the thickness is obtained. For example, the controller 7 recognizes an area having a thickness falling within a thickness monitoring range W2 (between less than 15 μm to less than 17 μm) in FIG. 11 as a specified area, and obtains the position (XY coordinates) of the recognized specified area.

In this second specified area recognition step, it is possible to recognize the specified area whose thickness is to be specified during the finishing grinding, in a short time. It is therefore possible to shorten the time required for grinding the wafer 100.

In the present embodiment, as shown in FIG. 1, the thickness measuring mechanism 80 includes the supporter 84, and this supporter 84 turns and moves the contactless thickness measurement device 82 along a radial direction of the chuck table 20 to pass through the center of the holding surface 22, by turning the arm portion 83 having the contactless thickness measurement device 82 at the leading end.

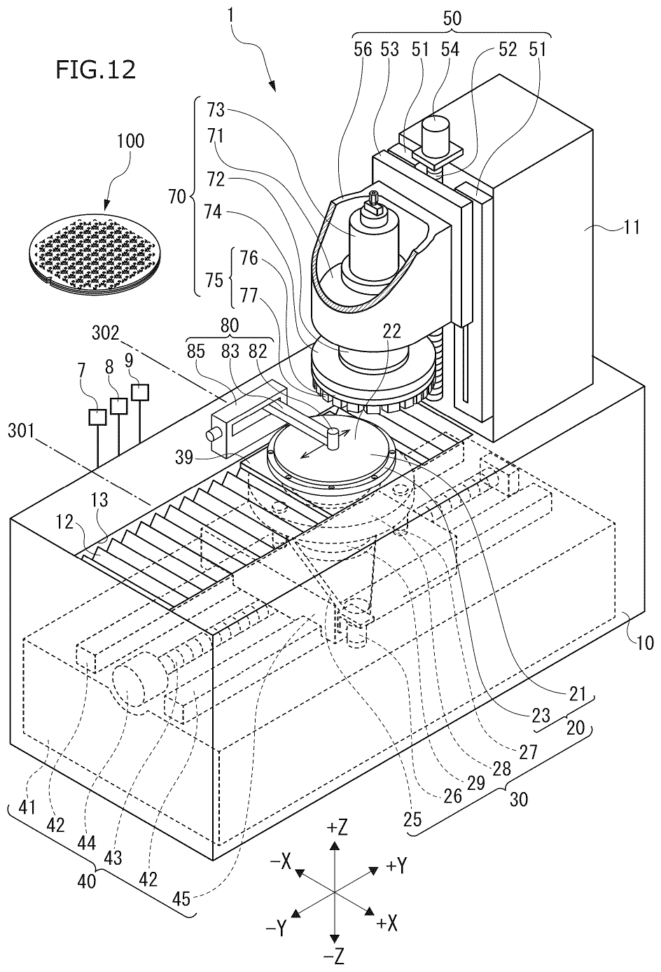

In this regard, as shown in FIG. 12, the thickness measuring mechanism 80 may include a linear mover 85 in place of the supporter 84. This linear mover 85 is configured to linearly move the contactless thickness measurement device 82 attached to the leading end of the arm portion 83 along a radial direction of the chuck table 20 to pass through the center of the holding surface 22, by linearly and horizontally moving, along the Y-axis direction, the arm portion 83 extending in the X-axis direction. This thickness measuring mechanism 80 having such an arrangement is able to suitably measure the thickness of the wafer 100, 200, 300 held by the chuck table 20 (i.e., the thickness of the chip 103, the device wafer 120, and the sealant 108).

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A method of grinding a composite wafer, comprising the steps of:
holding a support wafer of the composite wafer by a chuck table;
rotating the chuck table while relatively moving a contactless thickness measurement device and the chuck table in a radial direction of the chuck table, measuring the thickness of an area which is part of the composite wafer and whose thickness is measured by the contactless thickness measurement device at least during finishing grinding, and storing the measured thickness and XY coordinates of a point of measurement of thickness on a horizontal surface, as thickness data;
setting a specified area which is an area whose thickness is specified during the finishing grinding, by using the stored thickness data; and
measuring the thickness of the specified area by the contactless thickness measurement device by using the XY coordinates of the specified area, and grinding a top surface of the composite wafer by a grinding stone until a measured thickness becomes equal to a finished thickness set in advance.

2. The method of grinding the composite wafer according to claim 1, wherein,
the composite wafer includes the support wafer and chips provided on a top surface of the support wafer, and
the area whose thickness is measured includes part of at least one of the chips.

3. The method of grinding the composite wafer according to claim 1, wherein,
the composite wafer includes the support wafer and a device wafer provided on a top surface of the support wafer, and
the area whose thickness is measured includes part of the device wafer.

4. The method of grinding the composite wafer according to claim 1, wherein,
the step of setting the specified area includes the sub-steps of:
arranging the stored thickness data in XY coordinates in a two-dimensional manner;
allowing an operator to set a characteristic area that is an area having a characteristic, in the thickness data arranged in the two-dimensional manner; and
sampling the characteristic area from the thickness data by performing pattern matching for the thickness data arranged in the two-dimensional manner, by using the characteristic area, and recognizing the specified area in the thickness data based on a sampling result.

5. The method of grinding the composite wafer according to claim 1, wherein,
the step of setting the specified area includes the sub-step of
obtaining an area having a thickness falling within a thickness monitoring range set in advance, by using the stored thickness data, and recognizing the obtained area as the specified area.

6. A method of grinding a chip on wafer package in which chips are provided on a top surface of a support wafer and the chips are sealed with a sealant, comprising the steps of:
holding a support wafer of the chip on wafer package by a chuck table;
rotating the chuck table while relatively moving a contactless thickness measurement device and the chuck table in a radial direction of the chuck table, measuring (i) the thickness of the sealant from a top surface of the support wafer to a top surface of the sealant, which is the thickness of the sealant provided on the top surface of the support wafer of the chip on wafer package, and (ii) the thickness of the sealant from a top surface of at least one of the chips to the top surface of the sealant, which is the thickness of the sealant provided on the top surface of the at least one of the chips, at least at a part whose thickness is measured by the contactless thickness measurement device during finishing grinding, and storing the measured thickness and XY coordinates of a point of measurement of thickness on a horizontal surface, as thickness data;
setting a specified area which is an area whose thickness is specified during the finishing grinding, by using the stored thickness data; and
measuring the thickness of the specified area by the contactless thickness measurement device by using the XY coordinates of the specified area, and grinding a top surface of the chip on wafer package by a grinding stone until a measured thickness becomes equal to a finished thickness set in advance.

7. The method of grinding the chip on wafer package according to claim 6, wherein,
the step of setting the specified area includes the sub-step of:
arranging the stored thickness data in XY coordinates in a two-dimensional manner;
allowing an operator to set a characteristic area that is an area having a characteristic, in the thickness data arranged in the two-dimensional manner; and
sampling the characteristic area from the thickness data by performing pattern matching for the thickness data arranged in the two-dimensional manner, by using the characteristic area, and recognizing the specified area in the thickness data based on a sampling result.

8. The method of grinding the chip on wafer package according to claim 6, wherein,
the step of setting the specified area includes the sub-step of
obtaining an area having a thickness falling within a thickness monitoring range set in advance, by using the stored thickness data, and recognizing the obtained area as the specified area.
